(19) United States
(12) Patent Application Publication
(10) Pub. No.: US 2025/0120075 A1
(43) Pub. Date: Apr. 10, 2025

(54) MEMORY DEVICE AND METHOD OF MANUFACTURING THE SAME

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/607,090

(22) Filed: Mar. 15, 2024

(30) Foreign Application Priority Data
Oct. 4, 2023 (KR) 10-2023-0131699

(51) Int. Cl. H10B 41/27; G11C 5/06; H01L 23/528; H10B 41/10; H10B 43/10; H10B 43/27

(52) U.S. Cl. CPC H10B 41/27; G11C 5/063; H01L 23/5283; H10B 41/10; H10B 43/10; H10B 43/27

(57) ABSTRACT

A memory device, and a method of manufacturing the same, includes a gate stack formed on a cell region and a pass transistor region, a plurality of cell plugs extending in a vertical direction in the gate stack of the cell region, a plurality of gate contact structures extending in the vertical direction by passing through the gate stack of the pass transistor region, and a plurality of pass transistors connected to the plurality of respective gate contact structures. Each of the plurality of pass transistors has a cylindrical shape structure.

### CROSS-REFERENCE TO RELATED APPLICATION

The present application claims priority under 35 U.S.C. § 119 (a) to Korean patent application number 10-2023-0131699 filed on Oct. 4, 2023, in the Korean Intellectual Property Office, the entire disclosure of which is incorporated by reference herein.

### BACKGROUND

### 1. Technical Field

The present disclosure relates to an electronic device, and more particularly, to a memory device having a vertical channel structure and a method of manufacturing the same.

### 2. Related Art

A memory device is categorized as a volatile memory device or a nonvolatile memory device.

A write speed and a read speed of a nonvolatile memory device is relatively slow, however, the nonvolatile memory device maintains its stored data even when its power supply is cut off.

Therefore, a nonvolatile memory device is used to store data to be maintained regardless of power supply. A nonvolatile memory device includes read only memory (ROM), mask ROM (MROM), programmable, erasable programmable ROM (EPROM), electrically erasable programmable ROM (EEPROM), flash memory, phase change random-access memory (PRAM), magnetic RAM (MRAM), resistive RAM (RRAM), ferroelectric RAM (FRAM), and the like. The flash memory is divided into NOR type and NAND type.

### SUMMARY

According to an embodiment of the present disclosure, a memory device includes a gate stack formed on a cell region and a pass transistor region, a plurality of cell plugs extending in a vertical direction in the gate stack of the cell region, a plurality of gate contact structures extending in the vertical direction by passing through the gate stack of the pass transistor region, and a plurality of pass transistors connected to the plurality of respective gate contact structures, and each of the plurality of pass transistors has a cylindrical shape structure.

According to an embodiment of the present disclosure, a method of manufacturing a memory device includes forming a trench having a first depth at a boundary between a cell region and a pass transistor region and a plurality of first holes having a second depth in the pass transistor region by etching a first substrate including the cell region and the pass transistor region, forming an isolation structure by filling an insulating layer in the trench and forming a gate insulating layer on a sidewall of the plurality of first holes, forming channel patterns filling an inner portion of the plurality of first holes by growing the first substrate through an epitaxial growth method, forming a stack in which first material layers and second material layers are alternately stacked on the entire structure including the cell region and the pass transistor region, forming a plurality of cell plugs extending in a vertical direction in the stack of the cell region, replacing the second material layers with conductive patterns for word line, and forming a plurality of gate contact structures connected to the channel patterns through the stack of the pass transistor region.

According to an embodiment of the present disclosure, a memory device includes a gate stack including a plurality of interlayer insulating layer and a plurality of conductive pattern that are alternately stacked from a first surface to a second surface, a plurality of pass transistors arranged over the second surface of the gate stack, and a plurality of gate contact structures configured to extend from the first surface of the gate stack and the second surface of the gate stack, and each of the gate contact structures configured to connect each of the pass transistors and each of the conductive patterns.

### BRIEF DESCRIPTION OF THE DRAWINGS

FIG. 1 is a block diagram illustrating a memory device according to an embodiment of the present disclosure.

FIGS. 2A and 2B are perspective views illustrating an overlap structure of a peripheral circuit structure and a cell stack according to embodiments of the present disclosure.

FIG. 3 is a circuit diagram illustrating a memory cell array and a row decoder according to an embodiment of the present disclosure.

FIG. 4 is a cross-sectional view illustrating a memory device including a cell region and a pass transistor region of a cell stack according to an embodiment of the present disclosure.

FIGS. 5A, 5B, 6, 7A, 7B, and 8 to 24 are cross-sectional views and plan views illustrating a method of manufacturing a memory device according to an embodiment of the present disclosure.

FIG. 25 is a block diagram illustrating a configuration of a memory system according to an embodiment of the present disclosure.

FIG. 26 is a block diagram illustrating a configuration of a computing system according to an embodiment of the present disclosure.

### DETAILED DESCRIPTION

Specific structural and functional descriptions of embodiments according to the concepts which are disclosed in the present specification or application are illustrated only to describe the embodiments according to the concepts of the present disclosure. The embodiments according to the concepts of the present disclosure may be carried out in various forms and the scope of the present disclosure is not limited to the embodiments described in the present specification or application.

Hereinafter, embodiments of the present disclosure will be described with reference to the accompanying drawings to describe in detail enough to allow those of ordinary skill in the art to implement the technical idea of the present disclosure.

An embodiment of the present disclosure may improve process simplification an integration degree of a memory device by forming a pass transistor connected to a word line using a substrate on which a gate stack is formed. According to the present technology, process simplification an integration degree of a memory device may be improved by forming a pass transistor connected to a word line using a substrate on which a gate stack is formed.

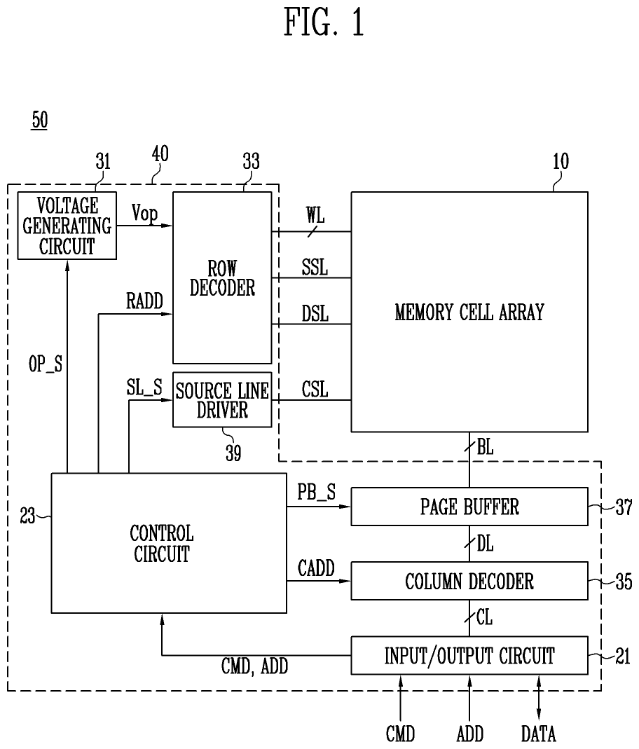

FIG. 1 is a block diagram illustrating a memory device according to an embodiment of the present disclosure.

Referring to FIG. 1, the memory device 50 may include a peripheral circuit 40 and a memory cell array 10.

The peripheral circuit 40 may be configured to perform an overall operation such as a program operation for storing data in the memory cell array 10, a read operation for outputting data stored in the memory cell array 10, and an erase operation for erasing data stored in the memory cell array 10. As an embodiment, the peripheral circuit 40 may include an input/output circuit 21, a control circuit 23, a voltage generating circuit 31, and a row decoder 33, a column decoder 35, a page buffer 37, and a source line driver 39.

The memory cell array 10 may include a plurality of memory cells in which data is stored. The memory cells may be arranged in three dimensions. The memory cell array 10 may include one or more cell strings. Each of the cell strings may include one or more drain select transistors, a plurality of memory cells, and one or more source select transistors connected between any one of bit lines BL and a common source line CSL. The one or more drain select transistors may be connected to a drain select line DSL, the plurality of memory cells may be connected to a plurality of word lines WL, and the one or more source select transistors may be connected to a source select line SSL.

The input/output circuit 21 may transmit a command CMD and an address ADD received from an external device (for example, a memory controller) of the memory device 50 to the control circuit 23. The input/output circuit 21 may transmit data DATA received from the external device to the column decoder 35, or output the data DATA received from the column decoder 35 to the external device.

The control circuit 23 may control the voltage generating circuit 31, the row decoder 33, the column decoder 35, the page buffer 37, and the source line driver 39 to perform the program operation, the read operation, or the erase operation in response to the command CMD and the address ADD received through the input/output circuit 21. For example, the control circuit 23 may generate and output an operation signal OP_S, a row address RADD, a source line control signal SL_S, a page buffer control signal PB_S, and a column address CADD in response to the command CMD and the address ADD.

The voltage generating circuit 31 may generate various operation voltages Vop used for the program operation, the read operation, or the erase operation in response to the operation signal OP_S.

The row decoder 33 may selectively transfer the operation voltages Vop generated in the voltage generating circuit 31 to the drain select line DSL, the word lines WL, and the source select line SSL in response to the row address RADD. In addition, the row decoder 33 may selectively discharge a voltage of the drain select line DSL, the word lines WL, and the source select line SSL.

The column decoder 35 may transmit the data DATA received from the input/output circuit 21 to the page buffer 37 in response to the column address CADD, or transmit the data DATA stored in the page buffer 37 to the input/output circuit 21. For example, during the program operation, the column decoder 35 may transmit the data DATA received through column lines CL from the input/output circuit 21 to the page buffer 37 in response to the column address CADD. During the read operation, the column decoder 35 may receive the data DATA stored in the page buffer 37 through data lines DL and transmit the received data DATA to the input/output circuit 21.

During the program operation, the page buffer 37 may

temporarily store the data DATA received from the column decoder 35, and controls a potential of the bit lines BL based on the temporarily stored data DATA. During the read operation, the page buffer 37 may sense the potential or a current amount of the bit lines BL and latch the data DATA according to a sensing result. The page buffer 37 may operate in response to the page buffer control signal PB_S.

The source line driver 39 may control a voltage applied to the common source line CSL in response to the source line control signal SL_S. For example, during the erase operation, the source line driver 39 may apply an erase voltage to the common source line CSL during the erase operation.

To improve an integration degree of the memory device, a cell stack of the memory cell array 10 may overlap the peripheral circuit 40. For example, after forming a peripheral circuit structure on a substrate, the cell stack may be formed by overlapping the cell stack on the peripheral circuit structure. Alternatively, after forming the cell stack and the peripheral circuit structure on different substrates, the peripheral circuit structure and the cell stack may be formed by overlapping the peripheral circuit structure and the cell stack by bonding the peripheral circuit structure and the cell stack to each other in a wafer bonding method.

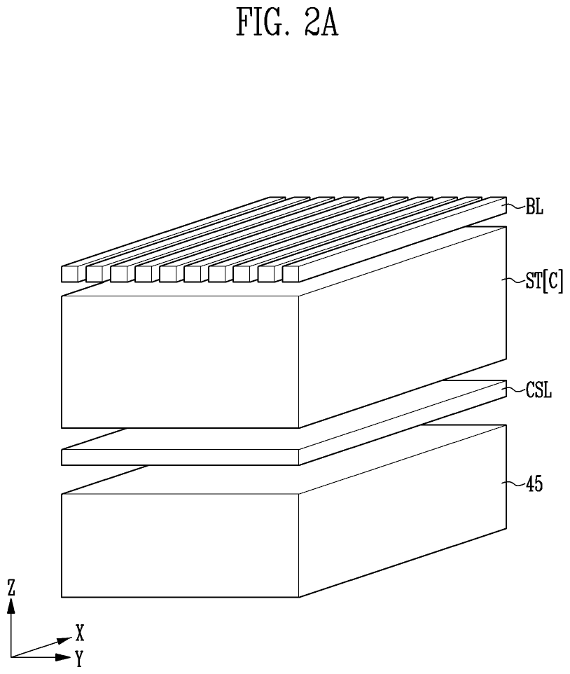

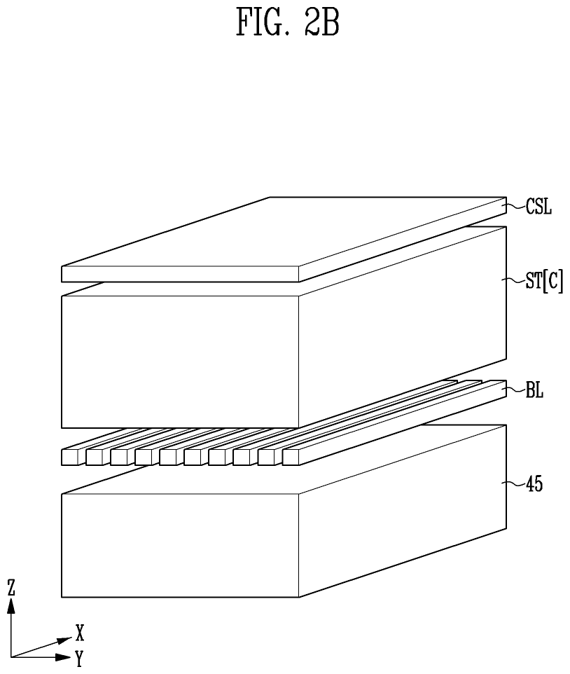

FIGS. 2A and 2B are perspective views illustrating an overlap structure of a peripheral circuit structure and a cell stack according to embodiments of the present disclosure.

Referring to FIGS. 2A and 2B, a common source line CSL and a plurality of bit lines BL may overlap on a peripheral circuit structure 45. A cell stack ST[C] may be disposed between the common source line CSL and the plurality of bit lines BL.

Referring to FIG. 2A, as an embodiment, the common source line CSL may be disposed between the cell stack ST[C] and the peripheral circuit structure 45, and the bit lines BL may overlap the common source line CSL with the cell stack ST[C] interposed therebetween.

Referring to FIG. 2B, as an embodiment, the bit lines BL may be disposed between the cell stack ST[C] and the peripheral circuit structure 45, and the common source line CSL may overlap the bit lines BL with the cell stack ST[C] interposed therebetween.

In the above-described embodiments of the present disclosure, the entire cell stack ST[C] overlaps on the peripheral circuit structure 45, but only a partial region of the cell stack ST[C] might overlap on the peripheral circuit structure 45. That is, a partial region of the cell stack ST[C] and a partial region of the peripheral circuit structure 45 might overlap each other.

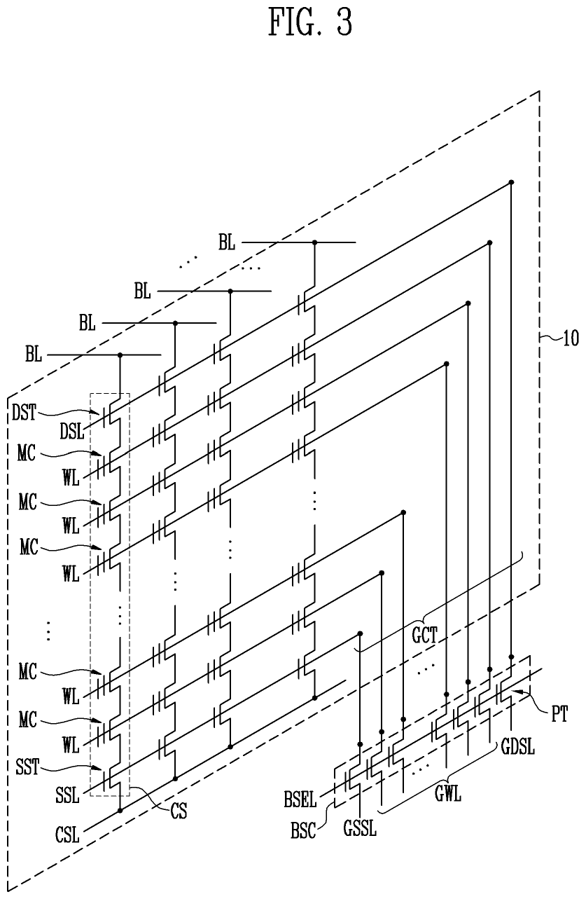

FIG. 3 is a circuit diagram illustrating a memory cell array and a row decoder according to an embodiment of the present disclosure.

Referring to FIG. 3, the memory cell array 10 may include a plurality of cell strings CS respectively connected to the plurality of bit lines BL. The plurality of cell strings CS may be commonly connected to the common source line CSL.

Each of the cell strings CS may include at least one source select transistor SST, a plurality of memory cells MC, and at least one drain select transistor DST disposed between the common source line CSL and the bit line BL.

The source select transistor SST may control an electrical connection between the cell string CS and the common source line CSL. The drain select transistor DST may control an electrical connection between the cell string CS and the bit line BL.

One source select transistor SST may be disposed or two or more source select transistors connected in series may be disposed between the common source line CSL and the plurality of memory cells MC. One drain select transistor DST may be disposed or two or more drain select transistors connected in series may be disposed between the bit line BL and the plurality of memory cells MC.

The plurality of memory cells MC may be respectively connected to the word lines WL. An operation of the plurality of memory cells MC may be controlled by cell gate signals applied to the word lines WL. The source select transistor SST may be connected to the source select line SSL. An operation of the source select transistor SST may be controlled by a source gate signal applied to the source select line SSL. The drain select transistor DST may be connected to the drain select line DSL. An operation of the drain select transistor DST may be controlled by a drain gate signal applied to the drain select line DSL.

The source select line SSL, the drain select line DSL, and the word lines WL may be connected to a block select circuit BSC. The block select circuit BSC may be included in the row decoder 33 described with reference to FIG. 1. As an embodiment, the block select circuit BSC may include pass transistors PT respectively connected to the source select line SSL, the drain select line DSL, and the word lines WL. Gates of the pass transistors PT may be connected to a block select line BSEL. The pass transistors PT may be configured to transfer operation voltages applied to global lines GSSL, GWL, and GDSL to the source select line SSL, the drain select line DSL, and the word lines WL in response to a block select signal applied to the block select line BSEL.

The block select circuit BSC may be connected to the source select line SSL, the drain select line DSL, and the word lines WL via gate contact structures GCT.

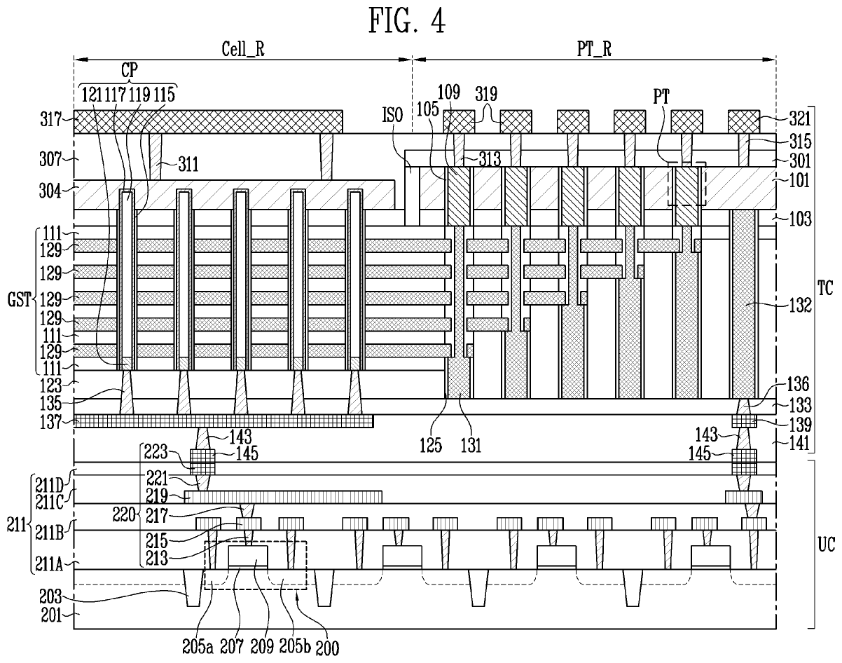

FIG. 4 is a cross-sectional view illustrating a memory device including a cell region and a pass transistor region of a cell stack according to an embodiment of the present disclosure. FIG. 4 illustrates a structure in which the cell stack of the memory cell array 10 of FIG. 1 and the peripheral circuit structure of the peripheral circuit 40 overlap.

Referring to FIG. 4, the memory device may be disposed so that a lower structure UC and an upper structure TC are bonded to each other.

A cell region Cell_R of the upper structure TC includes gate stacks GST, a plurality of cell plugs CP passing through the gate stacks GST, a bit line 137 disposed under the gate stack GST, and a source line 304 disposed on the gate stack GST.

The gate stack GST may include first material layers 111 as interlayer insulating layers and word line conductive patterns 129 which are alternately stacked in a vertical direction. A first insulating layer 103 may be disposed on the gate stack GST.

Each of the word line conductive patterns 129 may include various conductive materials such as a doped silicon layer, a metal layer, a metal silicide layer, and a barrier layer, and may include two or more types of conductive materials. For example, each of the word line conductive patterns 129 may include tungsten and a titanium nitride (TiN) layer surrounding a surface of the tungsten. The tungsten may be a low-resistance metal, and may lower a resistance of the word line conductive patterns 129. The titanium nitride layer (TiN) may be a barrier layer and may prevent direct contact between tungsten and the first material layers 111.

Among the word line conductive patterns 129, at least one conductive pattern adjacent to the bit line 137 may be used as the drain select line DSL of FIG. 3. Among the word line conductive patterns 129, at least one conductive pattern adjacent to the source line 304 may be used as the source select line SSL of FIG. 3. Among the word line conductive patterns 129, remaining conductive patterns except for the conductive pattern used as the drain select lines and the conductive pattern used as the source select lines may be used as the word lines WL of FIG. 3.

The cell plugs CP may pass through the gate stack GST and the first insulating layer 103 in the vertical direction, and one end of the cell plugs CP may be formed to protrude compared to the first insulating layer 103. For example, the cell plugs CP may extend in the vertical direction in the gate stack GST. The cell plugs CP may be formed as a hollow type. The cell plugs CP may include a core insulating layer 119 filling a central region, a doped semiconductor layer 121 positioned at a lower end of the core insulating layer 119, and a channel layer surrounding a surface of the core insulating layer 119 and the doped semiconductor layer 121. A channel layer 117 is used as a channel region of a cell string corresponding thereto. The channel layer 117 may be formed of a semiconductor material. As an embodiment, the channel layer 117 may include a silicon layer. A dopant may be implanted into a portion positioned at the uppermost portion of the channel layer 117, that is, a channel layer portion corresponding to the source select transistor, through an ion implantation process. The channel layer 117 may be formed to protrude compared to the first insulating layer 103 disposed on the gate stack GST. For example, the channel layer 117 may protrude compared to the first insulating layer 103 and extend into the source line 304. Accordingly, the channel layer 117 and the source line 304 are in direct contact. A memory layer 115 may be formed to surround a sidewall of the channel layer 117. The memory layer 115 may be disposed between the gate stack GST and the channel layer 117. The memory layer 115 may include a tunnel insulating layer surrounding the channel layer 117, a data storage layer surrounding the tunnel insulating layer, and a blocking insulating layer surrounding the data storage layer. The memory layer 115 may extend in the vertical direction along a sidewall of the channel layer 117 and may extend shorter than the channel layer 117. For example, the memory layer 115 may be formed between the channel layer 117 and the gate stack GST and between the channel layer 117 and the first insulating layer 103, and may have the same height as the first insulating layer 103.

The source line 304 may be formed to directly contact the channel layer 117 of the cell plugs CP that protrudes compared to the gate stack GST. The source line 304 may be configured by including at least one material among a dopant polysilicon layer, titanium nitride (TIN), tungsten (W), and copper (Cu).

The source line 304 may be connected to a line 317 through a source line contact 311 disposed through a sixth insulating layer 307.

The bit line 137 may be disposed under the gate stack GST. The bit line 137 may be connected to the cell plugs CP through bit line contacts 135 passing through a second insulating layer 123 and a third insulating layer 133.

A pass transistor region PT_R of the upper structure TC may include a gate stack GST, a plurality of gate contact structures 131, and a plurality of pass transistors PT.

The gate stack GST may be extended from the cell region Cell_R. For example, an edge portion of the gate stack GST may have a step structure. The plurality of gate contact structures 131 may be connected to the plurality of word line conductive patterns 129 of the gate stack GST. Further, the plurality of gate contact structures 131 may extend by passing through the gate stack GST in the vertical direction. The plurality of pass transistors PT may be arranged over each of the gate contact structures 131. For example, the gate stack GST may include a first surface and a second surface facing the first surface. The plurality of pass transistors PT may be arranged over the first surface of the gate stack GST. The plurality of gate contact structures 131 may extend from the first surface of gate stack GST to the second surface of the gate stack GST. For example, the pass transistor region PT_R may be a word line contact region for applying driving voltages to the plurality of word line conductive patterns 129.

The gate stack GST may extend to the pass transistor region PT_R, and extension lengths of the plurality of word line conductive patterns 129 included in the gate stack GST may be different from each other. For example, an extension length of the word line conductive pattern 129 disposed at the uppermost portion may be the longest, an extension length of the word line conductive pattern 129 disposed at the lowermost portion may be the shortest, as the word line conductive pattern 129 is disposed at an upper portion, the extension length may become longer, and thus the word line conductive pattern 129 may have a step shape.

The plurality of gate contact structures 131 may extend and may be disposed in the vertical direction in the pass transistor region PT_R and may pass through the plurality of word line conductive patterns 129 extending to the pass transistor region PT_R. In addition, each of the plurality of gate contact structures 131 may be directly connected to one of the corresponding plurality of word line conductive patterns 129. A spacer layer 125 may be disposed on a sidewall of each of the plurality of gate contact structures 131, and may be physically and electrically spaced apart from non-corresponding conductive patterns among the plurality of word line conductive patterns 129 by the spacer 125.

A pass transistor PT may be disposed on each of the plurality of gate contact structures 131. The pass transistor PT may have a cylindrical shape structure. For example, the pass transistor PT may include a channel pattern 109 having a cylindrical shape structure, a gate insulating layer 105 surrounding a sidewall of the channel pattern 109, and a first substrate 101 surrounding a sidewall of the gate insulating layer 105 and utilized as a gate electrode of the pass transistor.

A plurality of pass transistors PT disposed on each of the plurality of gate contact structures 131 may share the first substrate 101. The first substrate 101 may be a gate electrode of the plurality of pass transistors PT. The plurality of pass transistors PT may share a gate electrode. The first substrate 101 may be connected to a pass transistor contact structure 132, and the pass transistor contact structure 132 may extend in the vertical direction. A contact 136 passing through the third insulating layer 133 and a contact pad 139 connected to the contact 136 may be disposed under the pass transistor contact structure 132.

The plurality of pass transistors PT may be connected to a line 319 through a pass transistor contact 313 disposed through a fifth insulating layer 301 and the sixth insulating layer 307. The first substrate 101 may be connected to a line 321 through a pass transistor gate contact 315 disposed through the fifth insulating layer 301 and the sixth insulating layer 307.

An isolation structure ISO may be disposed between the pass transistor region PT_R and the cell region Cell_R, and the isolation structure ISO may prevent the first substrate 101 from extending into the cell region Cell_R. The isolation structure ISO may be formed of the same material as the gate insulating layer 105. That is, the isolation structure ISO is disposed at a boundary between the pass transistor region PT_R and the cell region Cell_R on the gate stack GST, and physically and electrically isolates the source line 304 of the cell region Cell_R and the first substrate 101 of the pass transistor region PT_R.

A first connection structure may be formed in a fourth insulating layer 141 covering the bit line 137 and the contact pad 139. The first connection structure may include contacts 143 connected to each of the bit line 137 and the contact pad 139, and first bonding metals 145 connected to the contacts 143 and having a surface exposed to an outside.

The lower structure UC may include a complementary metal oxide semiconductor (CMOS) circuit structure CMOS including a plurality of transistors 200 formed on a substrate 201, and a second connection structure formed on the CMOS circuit structure CMOS. The plurality of transistors 200 may be spaced apart from each other by an element isolation structure 203.

The second connection structure may include an insulating structure 211 formed on the substrate 201 and connection structures 220 formed inside the insulating structure 211. Each of the connection structures 220 may include various conductive patterns 213, 215, 217, 219, 221, and 223 embedded within the insulating structure 211. The insulating structure 211 may include two or more insulating layers 211A to 211D sequentially stacked. The conductive pattern 223 may be defined as a second bonding metal.

The upper structure TC and the lower structure UC may have a structure in which the upper structure TC and the lower structure UC are bonded to each other by a bonding process. For example, the exposed first bonding metals 145 of the first connection structure of the upper structure TC and the exposed second bonding metal 223 of the second connection structure of the lower structure UC may be disposed to face each other and may be bonded to each other.

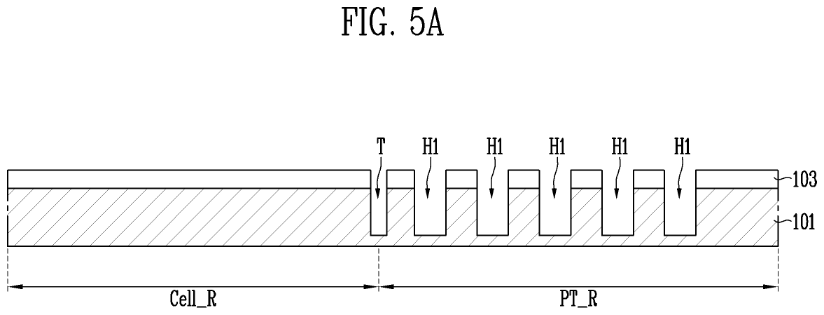

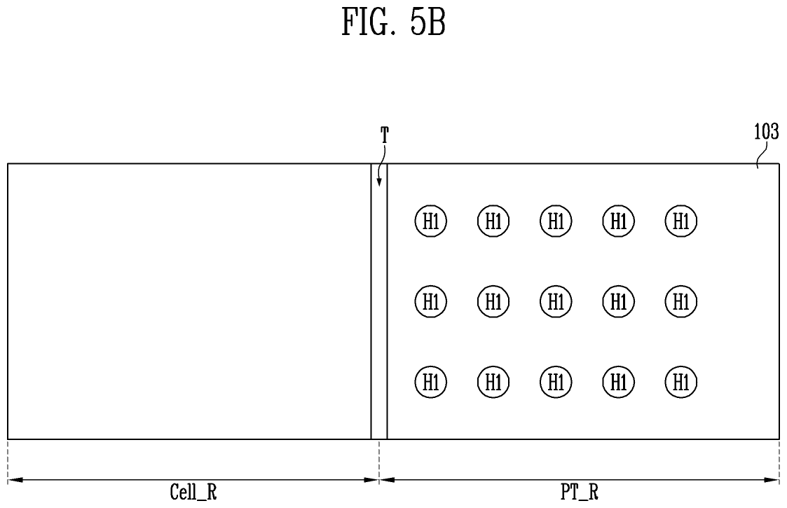

FIGS. 5A, 5B, 6, 7A, 7B, and 8 to 24 are cross-sectional views and plan views illustrating a method of manufacturing a memory device according to an embodiment of the present disclosure.

FIGS. 5A, 5B, 6, 7A, 7B, and 8 to 16 are cross-sectional views and plan views illustrating a method of forming a cell stack and a pass transistor.

Referring to FIGS. 5A and 5B, the first insulating layer 103 is formed on the first substrate 101. The first substrate 101 may be a bulk silicon substrate, a silicon-germanium substrate, or an epitaxial thin film formed through a selective epitaxial growth method. The first insulating layer 103 may be an oxide layer.

Thereafter, the trench T extending into the first substrate 101 by passing through the first insulating layer 103 along the boundary of the cell region Cell_R and the pass transistor region PT_R is formed. In addition, a plurality of first holes H1 extending into the first substrate 101 by passing through the first insulating layer 103 of the pass transistor region PT_R are formed. The plurality of first holes H1 are a region where the pass transistors PT of FIG. 3 are formed. A depth of the trench T may be equal to a depth of the plurality of first holes H1, or the depth of the trench T may be formed deeper than the depth of the plurality of first holes H1.

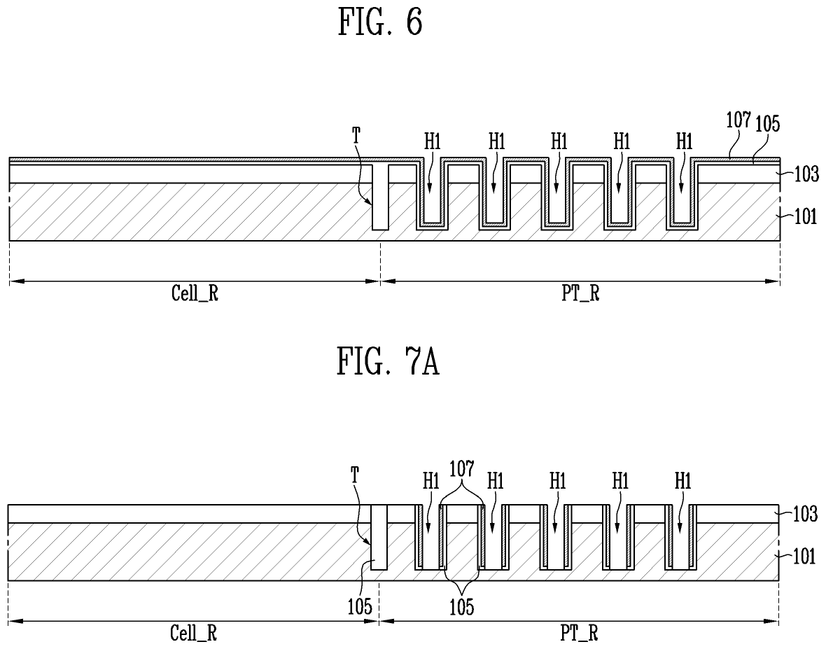

Referring to FIG. 6, the gate insulating layer 105 is formed on the entire structure. The gate insulating layer 105 may be formed so that the trench T is buried. The gate insulating layer 105 formed in the trench T may be defined as an isolation structure. The gate insulating layer 105 may be formed in a liner shape along a sidewall and a lower surface of the plurality of first holes H1. The gate insulating layer 105 may be an oxide layer.

Thereafter, a first sacrificial layer 107 is formed along an upper surface of the gate insulating layer 105. The first sacrificial layer 107 may be a nitride layer.

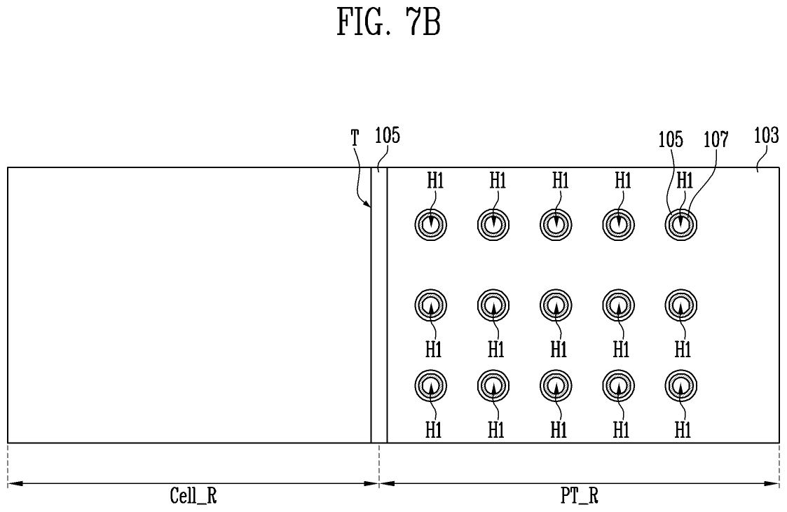

Referring to FIGS. 7A and 7B, the first sacrificial layer 107 and the gate insulating layer 105 are etched by performing an etch-back process to expose the first substrate 101 through the lower surface of the plurality of first holes H1. By the etch-back process, the gate insulating layer 105 remains only on a sidewall of the trench T and the plurality of first holes H1, and the first sacrificial layer 107 remains only on a sidewall of the gate insulating layer 105 remaining on the sidewall of the plurality of first holes H1.

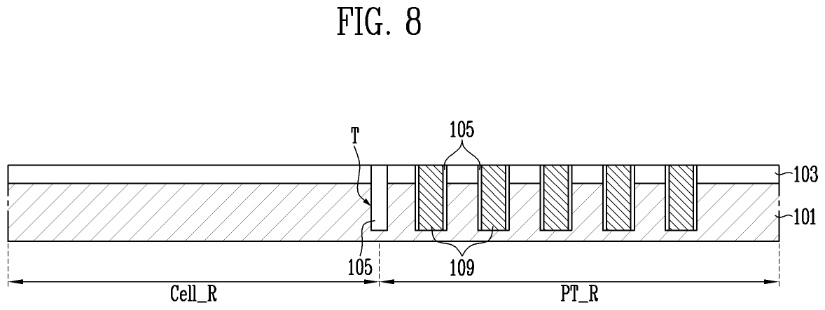

Referring to FIG. 8, the first sacrificial layer 107 of FIG. 7A is removed. Thereafter, the channel pattern 109 filling an inside of the plurality of first holes H1 is formed by growing the first substrate 101 through an epitaxial growth method. Accordingly, the channel pattern 109 and the gate insulating layer 105 for the pass transistor are disposed inside the plurality of first holes H1. The first substrate 101 may be used as a gate electrode of the pass transistor, the gate insulating layer 105 may be used as a gate insulating layer of the pass transistor, and the channel pattern 109 may be used as a channel of the pass transistor. Accordingly, the pass transistor may be configured of the channel pattern 109 of the cylindrical shape structure, the gate insulating layer 105 surrounding a sidewall of the channel pattern 109, and the first substrate 101 surrounding a sidewall of the gate insulating layer.

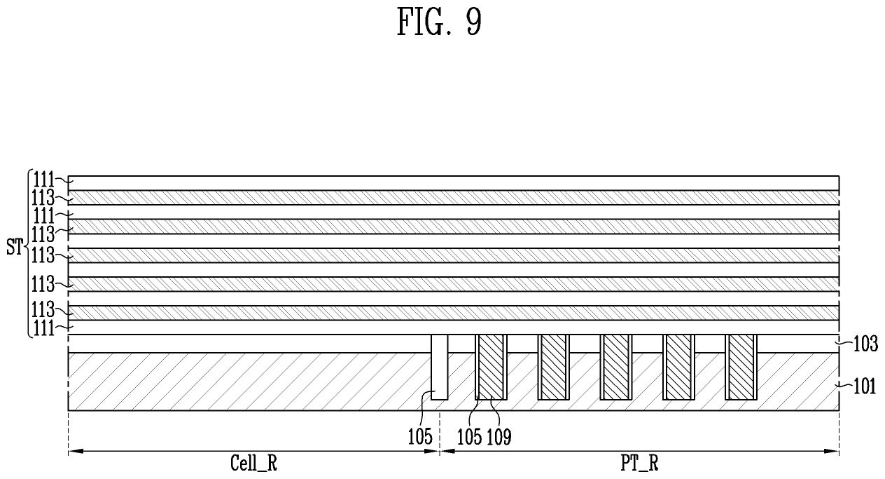

Referring to FIG. 9, the stack ST may be formed on the entire structure of the cell region Cell_R and the pass transistor region PT_R. The stack ST may include a plurality of first material layers 111 and a plurality of second material layers 113 alternately stacked. For example, the first material layers 111 may be interlayer insulating layers. The second material layers 113 may be sacrificial layers.

The second material layers 113 may include a material having an etch rate different from that of the first material layers 111. For example, the first material layers 111 may include silicon oxide, and the second material layers 113 may include silicon nitride. The following drawing illustrates an embodiment in which the first material layers 111 are formed as interlayer insulating layers and the second material layers 113 are formed as sacrificial layers, but the present disclosure is not limited thereto. A physical property of the first material layers 111 and the second material layers 113 may be variously changed.

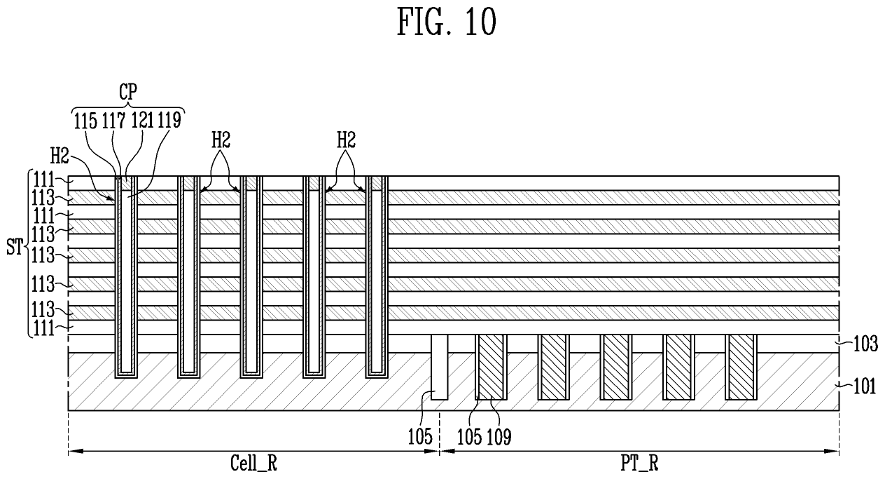

Referring to FIG. 10, the plurality of cell plugs CP are formed on the cell region Cell_R. The plurality of cell plugs CP may pass through the stack ST and the first insulating layer 103 in the vertical direction and extend into the first substrate 101 in a certain depth.

A process of forming the plurality of cell plugs CP is described in more detail as follows.

An etching process is performed to form second holes H2 extending into the first substrate 101 in a certain depth by passing through the stack ST and the first insulating layer 103.

Thereafter, the memory layer 115 and the channel layer 117 may be formed inside the second holes H2. A sidewall of the channel layer 117 and the channel layer 117 extending into the first substrate 101 may be surrounded by the memory layer 115.

Forming the memory layer 115 may include sequentially stacking a data storage layer and a tunnel insulating layer on a surface of the second holes H2. The memory layer 115 may be formed in a liner shape, and a central region of the second holes H2 may be defined by the memory layer 115. In addition, the memory layer 115 may further include a blocking insulating layer, and the blocking insulating layer may be formed on the surface of the second holes H2 before forming the data storage layer.

Thereafter, the channel layer 117 may be formed on a surface of the memory layer 115. The channel layer 117 may include a semiconductor layer used as a channel region. For example, the channel layer 117 may include undoped polysilicon.

As an embodiment, the channel layer 117 may be formed in a liner shape, and the central region of the second holes H2 may include a portion that is not filled with the channel layer 117. When the channel layer 117 is formed in the liner shape, filling the central region of the second holes H2 with the core insulating layer 119, defining a recess region in a portion of the central region of the second holes H2 by etching an upper end portion of the core insulating layer 119, and filling the recess region with a doped semiconductor layer 121 may be included. The core insulating layer 119 may include an oxide, and the doped semiconductor layer 121 may include a conductive dopant. The conductive dopant may include an n-type dopant for a junction. The conductive dopant may include a counter-doped p-type dopant.

As another embodiment, the channel layer 117 may be formed to fill the central region of the second holes H2, and the core insulating layer 119 and the doped semiconductor layer 121 may be omitted. When the core insulating layer 119 and the doped semiconductor layer 121 are omitted, forming the channel layer 117 may further include doping an inside of the channel layer 117 with the conductive dopant.

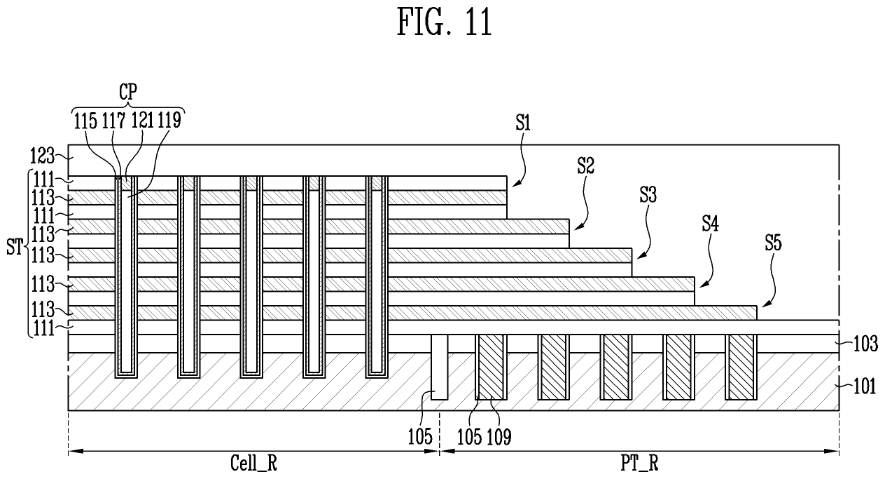

Referring to FIG. 11, the stack structure ST of the pass transistor region PT_R is etched to form a plurality of step structures S1 to S5. Each of the step structures S1 to S5 may include one layer of second material layer 113. In the step structure S1 positioned at the uppermost portion, the first material layer 111 may be disposed at the uppermost portion, and the remaining step structures S2 to S5 may be formed so that an upper surface of the second material layer 113 is exposed.

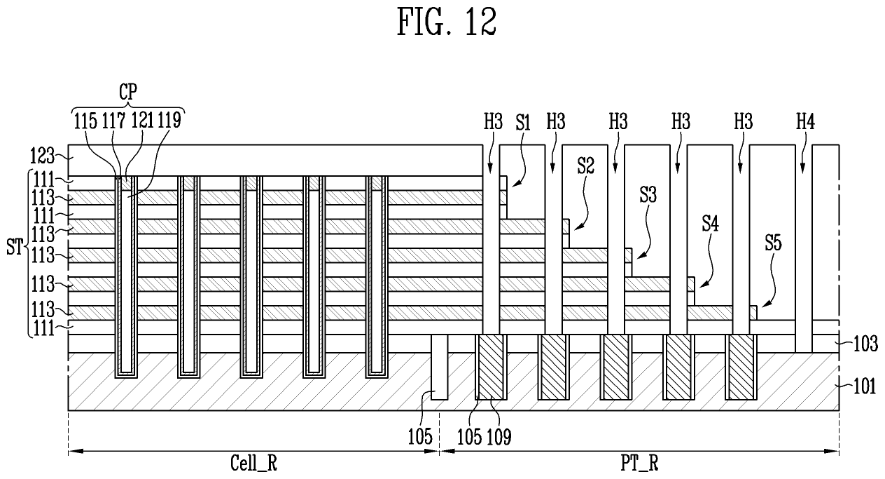

Referring to FIG. 12, the second insulating layer 123 is formed on the entire structure including the plurality of step structures S1 to S5. After forming the second insulating layer 123, a planarization process may be performed so that the upper surface to be flat.

Thereafter, a plurality of third holes H3 exposing the channel pattern 109 by passing through the second insulating layer 123 and the stack ST of the pass transistor region PT_R are formed. Each of the plurality of third holes H3 may be disposed to pass through the plurality of step structures S1 to S5. The plurality of third holes H3 may extend into the channel patterns 109 in a certain depth.

In addition, a fourth hole H4 exposing the first substrate 101 by passing through the second insulating layer 123 of the pass transistor region PT_R, the first material layer 111 of the lowermost portion, and the first insulating layer 103 is formed.

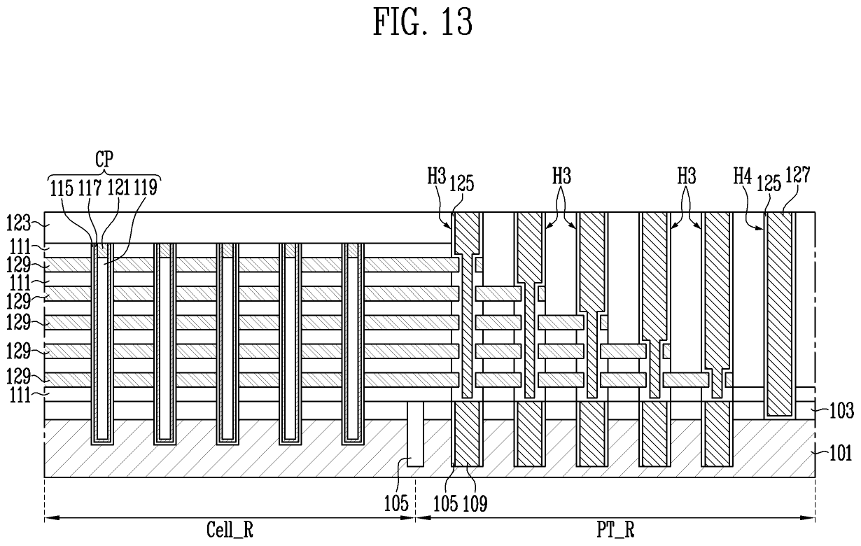

Referring to FIG. 13, an irregularity may be formed on a sidewall of the plurality of third holes H3 by etching the second insulating layer 123 and the first material layers 111 exposed through the sidewall of the plurality of third holes H3 in a certain thickness. In addition, a critical dimension may be expanded by etching the second insulating layer 123, the first material layers 111, and the first insulating layer 103 exposed through a sidewall of the fourth hole H4 in a certain thickness.

Thereafter, a spacer layer 125 is formed along the sidewall and a lower surface of the plurality of third holes H3 and the fourth hole H4. The spacer layer 125 may be an oxide layer. The spacer layer 125 may be formed to cover the sidewall irregularities of each of the plurality of third holes H3. For example, the spacer layer 125 may be formed to have non-uniform thickness based on a difference of material properties between the first material layer 111 and the second material layer 113, and a depositing method of the spacer layer 125.

Thereafter, a support structure 127 is formed in a central region of the plurality of third holes H3 and the fourth hole H4. The support structure 127 may support the stack ST so that the stack ST is not collapsed during a subsequently performed process of removing the second material layers 113. The support structure 127 may be a polysilicon layer.

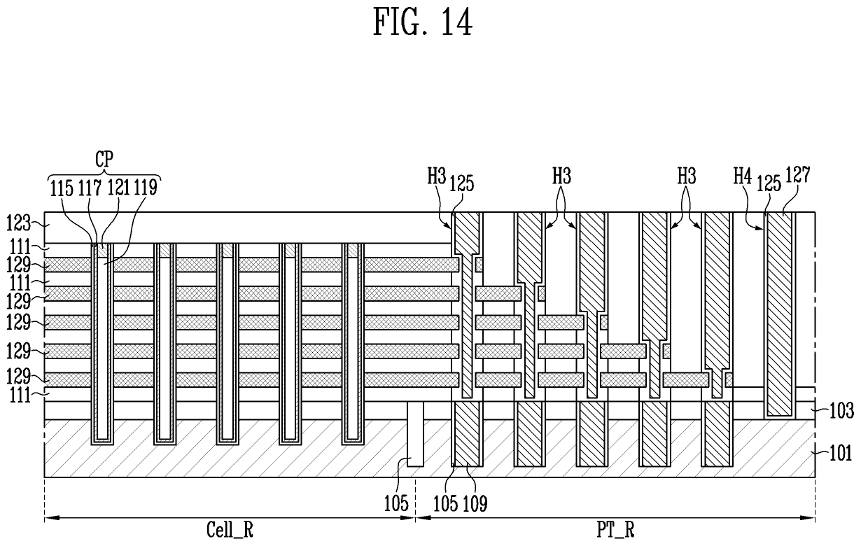

Referring to FIG. 14, a sidewall of the stack ST is exposed by forming a slit (not shown) passing through the second insulating layer 123 and the stack ST. The slit (not shown) may be formed in a line shape extending from the cell region Cell_R to the pass transistor region PT_R.

Thereafter, the second material layers 113 of FIG. 13 of the stack ST exposed through the slit (not shown) are removed, and the word line conductive patterns 129 are formed in a space from which the second material layers are removed. The word line conductive patterns 129 may be penetrated by the cell plugs CP, and each of the word line conductive patterns 129 is formed to surround the cell plugs CP at different heights. The word line conductive patterns 129 may include various conductive materials such as a doped silicon layer, a metal layer, a metal silicide layer, and a barrier layer, and may include two or more types of conductive materials. For example, each of the word line conductive patterns 129 may include tungsten and a titanium nitride TiN layer surrounding a surface of the tungsten. The tungsten may be a low-resistance metal, and may lower the resistance of the word line conductive patterns 129. The titanium nitride TiN may be a barrier layer, and may prevent direct contact between tungsten and interlayer insulating layers.

A blocking insulating layer (not shown) may be formed to surround a sidewall of the cell plugs CP exposed through the space where the second material layers 113 of FIG. 13 are removed before forming the word line conductive patterns 129. The blocking insulating layer may be formed of an aluminum oxide layer AL₂O₃.

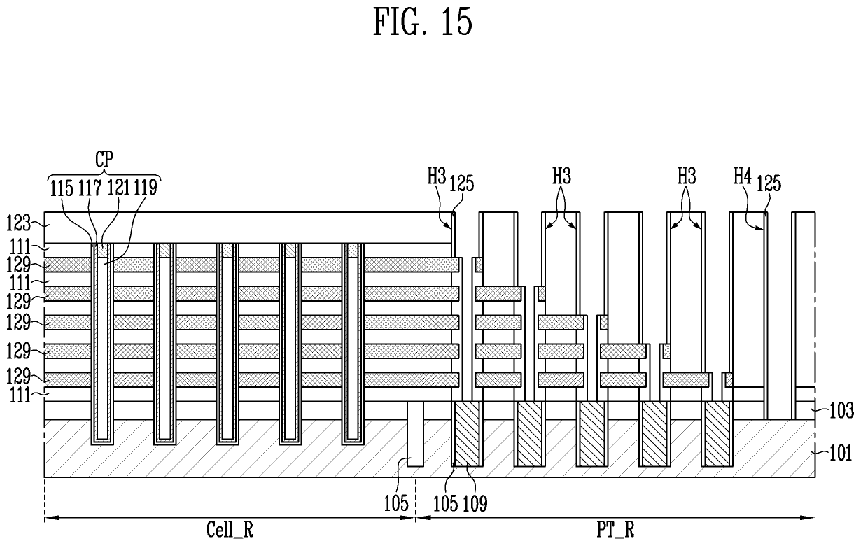

Referring to FIG. 15, the support structure 127 of FIG. 14 is removed. Thereafter, a dry etching process is performed to etch a portion of the exposed spacer layer 125 to expose a portion of an upper surface of the word line conductive pattern 129 disposed at the uppermost portion among the word line conductive patterns 129 penetrated by each of the plurality of third holes H3. In addition, the spacer layer 125 formed on a lower surface of each of the plurality of third holes H3 and the fourth hole H4 is removed to expose the channel patterns 109 and the first substrate 101.

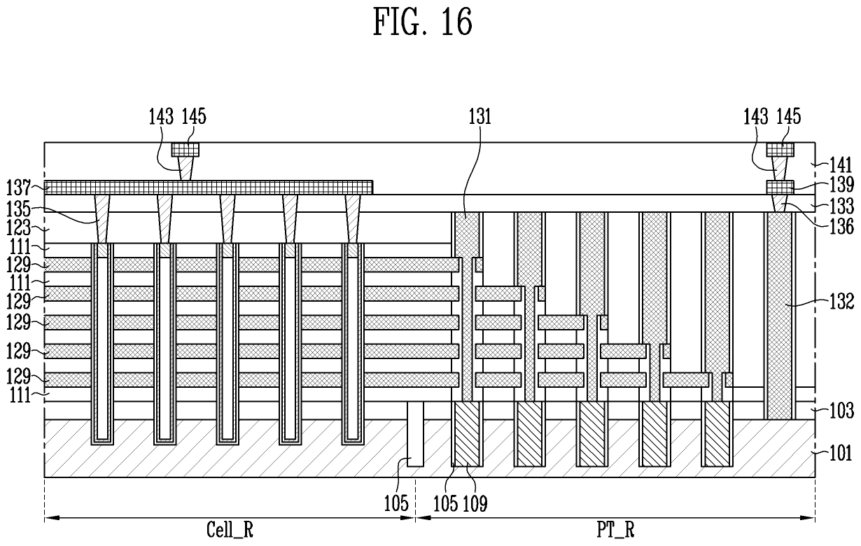

Referring to FIG. 16, by performing an ion implantation process, ions are implanted to the channel patterns 109 exposed through the plurality of third holes H3 and inside of the first substrate 101 exposed through the fourth hole H4, and a rapid thermal annealing (RTA) process may be performed.

The gate contact structures 131 are formed by filling an inside of the plurality of third holes H3 with a conductive material, and the pass transistor contact structure 132 is formed by filling an inside of the fourth hole H4 with a conductive material. The gate contact structures 131 may be directly connected to the corresponding word line conductive patterns 129 and the corresponding channel patterns 109. In addition, the pass transistor contact structure 132 may be directly connected to the first substrate 101.

Thereafter, the third insulating layer 133 is formed on the entire structure, and the bit line contacts 135 connected to an upper end portion of the cell plugs CP by passing through the third insulating layer 133 are formed. In addition, the contact 136 connected to an upper end portion of the pass transistor contact structure 132 by passing through the third insulating layer 133 is formed.

Thereafter, the bit line 137 connected to the bit line contacts 135 and the contact pad 139 connected to the contact 136 are formed on the third insulating layer 133.

Thereafter, after forming the fourth insulating layer 141 on the entire structure, the contacts 143 connected to the bit line 137 and the contact pad 139 and the first bonding metals 145 having a surface connected to the contacts and exposed to the outside are formed.

The contacts 143 and the first bonding metals 145 having the surface connected to the contacts 143 and exposed to the outside may be defined as first connection structures.

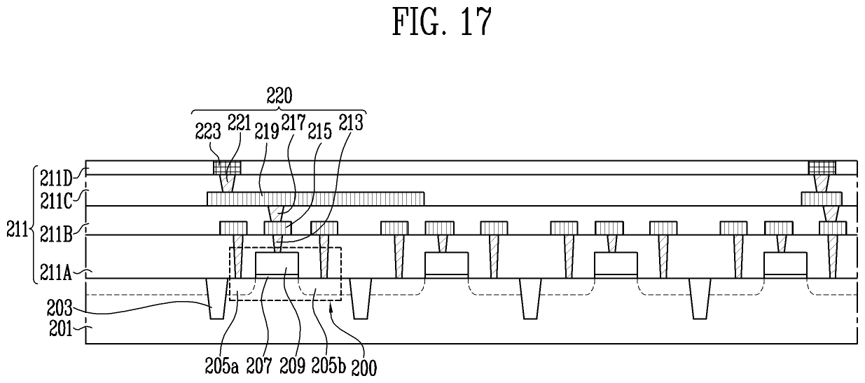

FIG. 17 is a cross-sectional view illustrating a step of forming a CMOS circuit and second connection structures on a second substrate.

Forming a plurality of transistors 200 configuring a complementary metal oxide semiconductor (CMOS) circuit on the second substrate 201 may be included.

The second substrate 201 may be a bulk silicon substrate, a silicon-on-insulator substrate, a germanium substrate, a germanium-on-insulator substrate, a silicon-germanium substrate, or an epitaxial layer formed through a selective epitaxial growth method.

Each of the transistors 200 may be formed in an active region of the second substrate 201 partitioned by an element isolation layer 203. Each of the transistors 200 may include a gate insulating layer 207 and a gate electrode 209 stacked on an active region corresponding thereto, and junctions 205a and 205b formed in the active region of both sides of the gate electrode 209. The junctions 205a and 205b may include a conductive dopant to implement a transistor corresponding thereto. The junctions 205a and 205b may include at least one of an n-type dopant or a p-type dopant.

After forming the plurality of transistors 200, the second connection structures 220 connected to the transistors 200 configuring the CMOS circuit, and the second insulating structure 211 covering the second connection structures 220 and the transistors 200 may be formed.

The second insulating structure 211 may include two or more insulating layers 211A to 211D. The second connection structures 220 may be buried in the second insulating structure 211. Each of the second connection structures 220 may include a plurality of conductive patterns 213, 215, 217, 219, 221, and 223. The second insulating structure 211 and the second connecting structures 220 are not limited to an example shown in the drawing and may be variously changed.

The conductive patterns 213, 215, 217, 219, 221, and 223 included in each of the second connection structures 220 may include a second bonding metal 223 having a surface exposed to an outside of the second insulating structure 211.

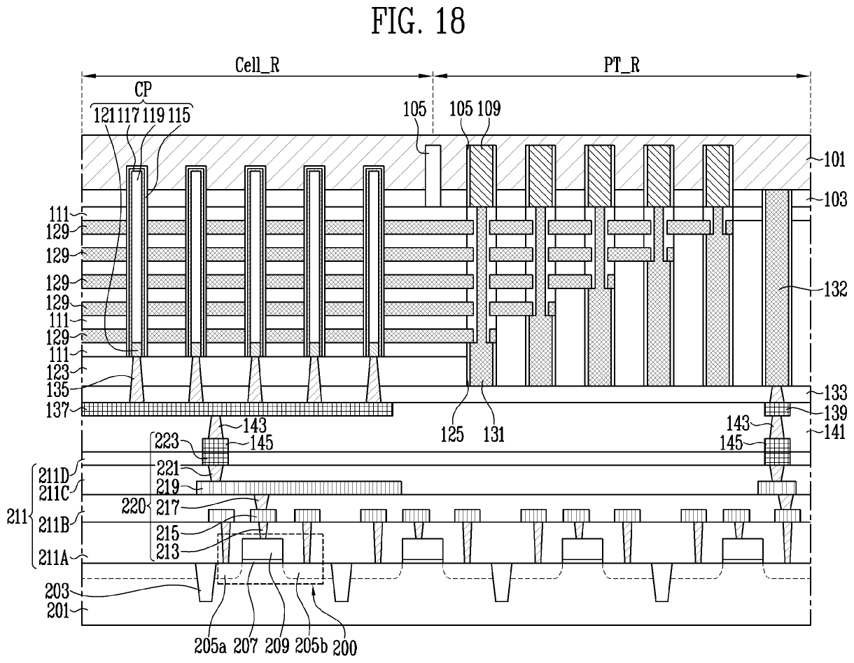

FIG. 18 is a cross-sectional view illustrating a step of bonding the first connection structures and the second connection structures to each other.

Referring to FIG. 18, the first substrate 101 and the second substrate 201 are arranged so that the first bonding metal 145 on the first substrate 101 and the second bonding metal 145 on the second substrate 201 may be bonded to each other. The first bonding metal 145 and the second bonding metal 223 may include various metals, for example, may include copper.

Thereafter, the first bonding metal 145 and the second bonding metal 223 are bonded to each other. To this end, after applying heat to the first bonding metal 145 and the second bonding metal 223, the first bonding metal 145 and the second bonding metal 223 may be hardened. The present disclosure is not limited thereto, and various processes for connecting the first bonding metal 145 and the second bonding metal 223 may be introduced.

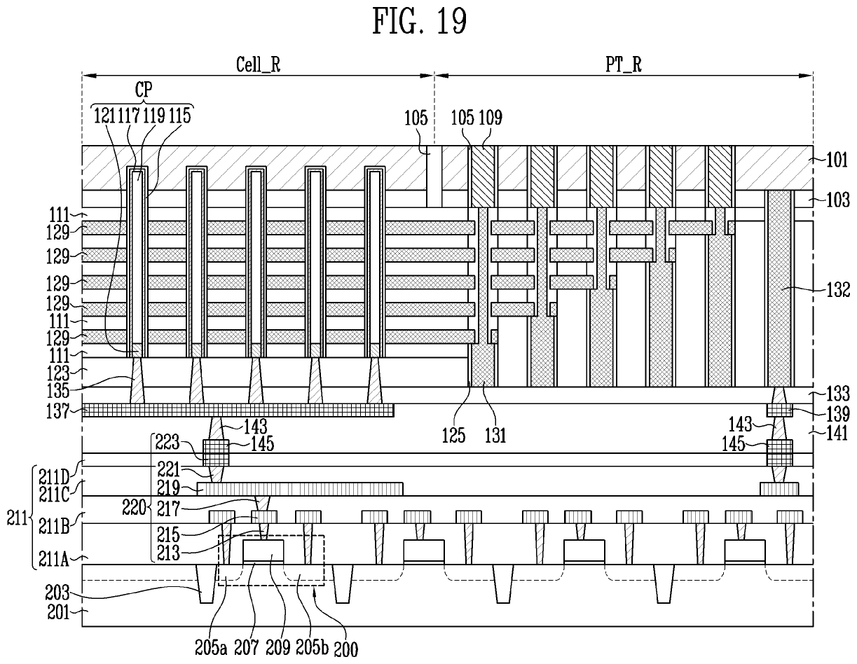

FIGS. 19 to 24 are cross-sectional views illustrating a steps of forming a source line connected to a plurality of cell plugs and a line connected to pass transistors.

Referring to FIG. 19, the first substrate 101 is etched to expose the channel pattern 109 and the gate insulating layer 105 in the trench T. For example, the first substrate 101 is etched to narrow its thickness by performing a chemical mechanical polishing (CMP) process to expose the channel pattern 109 and the gate insulating layer 105 in the trench T.

The first substrate 101 of the cell region Cell_R and the first substrate 101 of the pass transistor region PT_R may be physically and electrically separated from each other by the exposed gate insulating layer 105 in the trench T, and the first substrate 101 of the pass transistor region PT_R may be used as a gate electrode of the pass transistors.

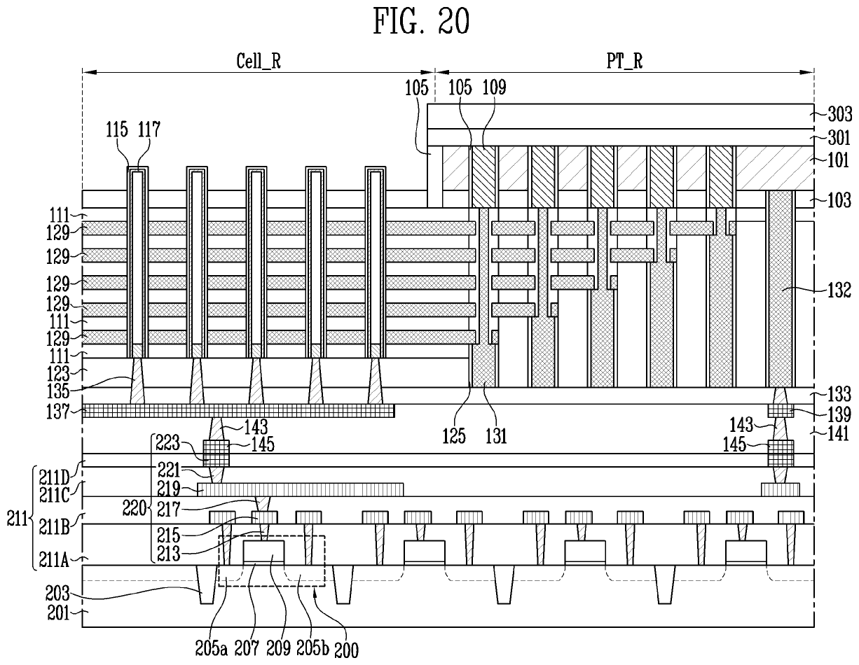

Referring to FIG. 20, the fifth insulating layer 301 is formed on the entire structure including the first substrate 101 of the cell region Cell_R and the pass transistor region PT_R. Thereafter, a first mask pattern 303 in which the cell region Cell_R is opened is formed on the fifth insulating layer 301. The first mask pattern 303 may be a photoresist pattern.

Thereafter, the fifth insulating layer 301 and the first substrate 101 of the cell region Cell_R opened by the first mask pattern 303 are removed by etching. Accordingly, the cell plugs CP protrude by passing through the first insulating layer 103.

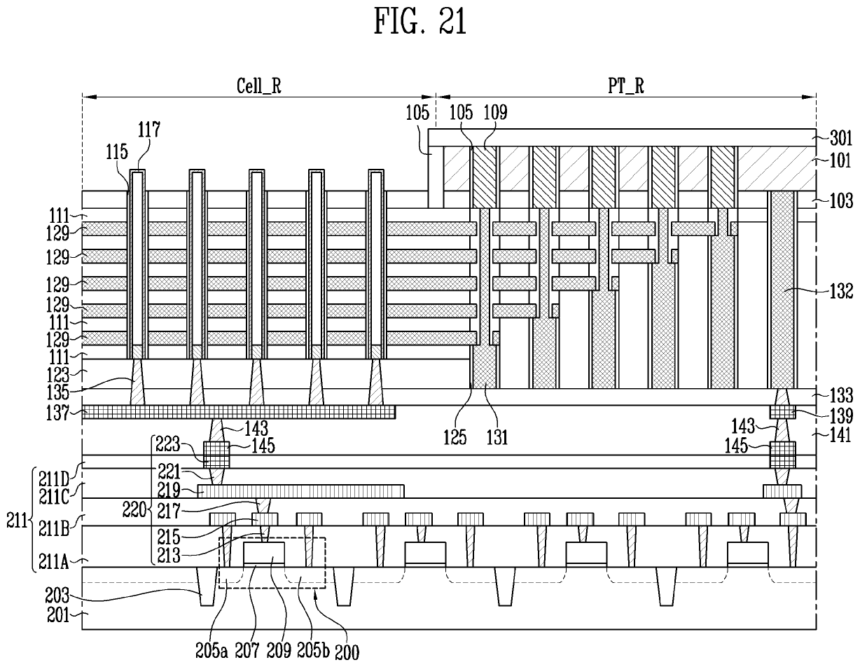

Referring to FIG. 21, the exposed memory layer 115 of the protruding cell plugs CP is etched to expose the channel layer 117 of the protruding cell plugs CP. The first mask pattern 303 of FIG. 20 may be removed before or after an etching process of the memory layer 115.

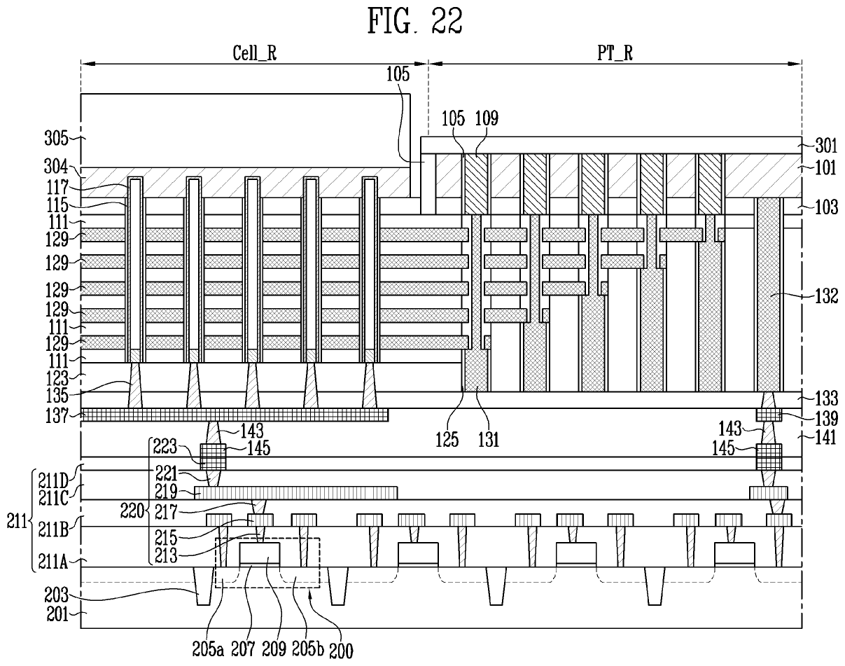

Referring to FIG. 22, the source line 304 is formed to cover the exposed channel layer 117 of the cell plugs CP. The source line 304 may include at least one material among a dopant polysilicon layer, titanium nitride (TiN), tungsten W, and copper (Cu).

Thereafter, a second mask pattern 305 which overlaps the cell plugs CP and in which the pass transistor region PT_R is opened is formed on the source line 304, and the source line 304 formed on the pass transistor region PT_R opened by the second mask pattern 305 is removed by etching.

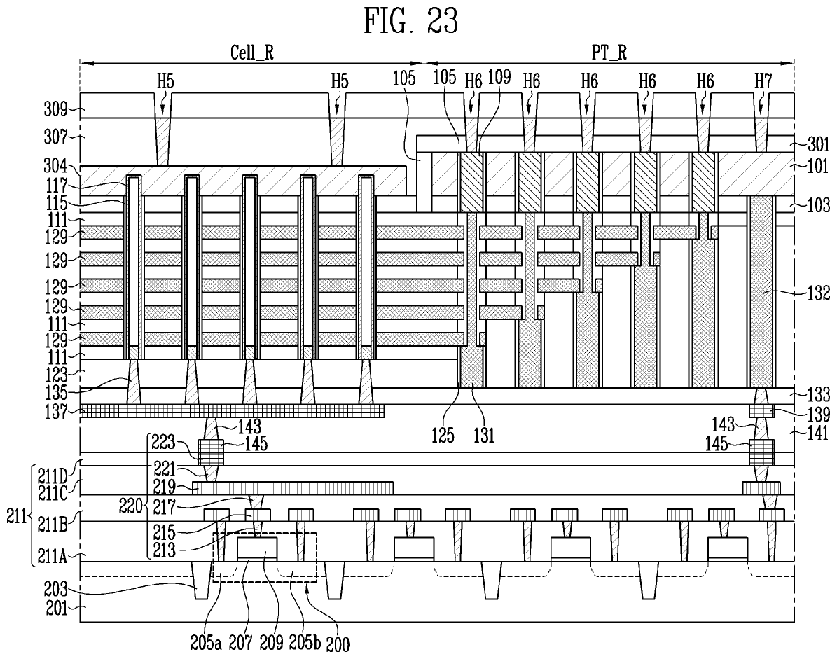

Referring to FIG. 23, the second mask pattern 305 of FIG. 22 is removed, and the sixth insulating layer 307 is formed on the entire structure including the cell region Cell_R and the pass transistor region PT_R. The sixth insulating layer 307 may be an oxide layer.

Thereafter, a fourth mask pattern 309 in which a region overlapping the source line 304, regions overlapping the plurality of channel patterns 109, and a region overlapping the first substrate 101 are opened is formed, and the sixth insulating layer 307 opened by the fourth mask pattern 309 is etched to form at least one fifth hole H5 exposing the source line 304, a plurality of sixth holes H6 exposing the plurality of channel patterns 109 and a seventh hole H7 through which the first substrate 101 is exposed.

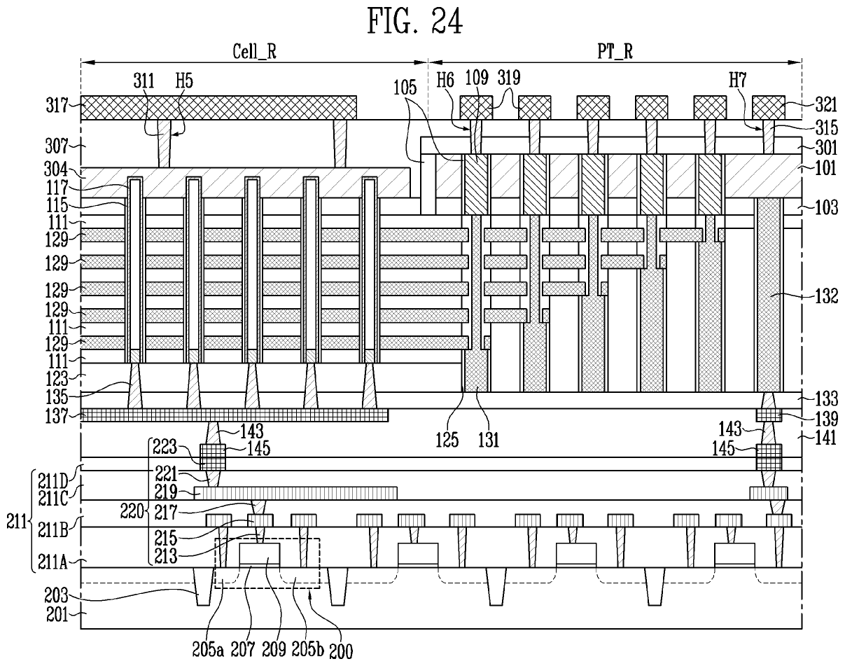

Referring to FIG. 24, a conductive material is buried in at least one fifth hole H5 to form the source line contact 311. Thereafter, the line 317 connected to the source line contact 311 is formed.

In addition, a conductive material is buried in the plurality of sixth holes H6 to form the pass transistor contact 313. Thereafter, the line 319 connected to the pass transistor contact 313 is formed.

In addition, a conductive material is buried in the seventh hole H7 to form the pass transistor gate contact 315. Thereafter, the line 321 connected to the pass transistor gate contact 315 is formed.

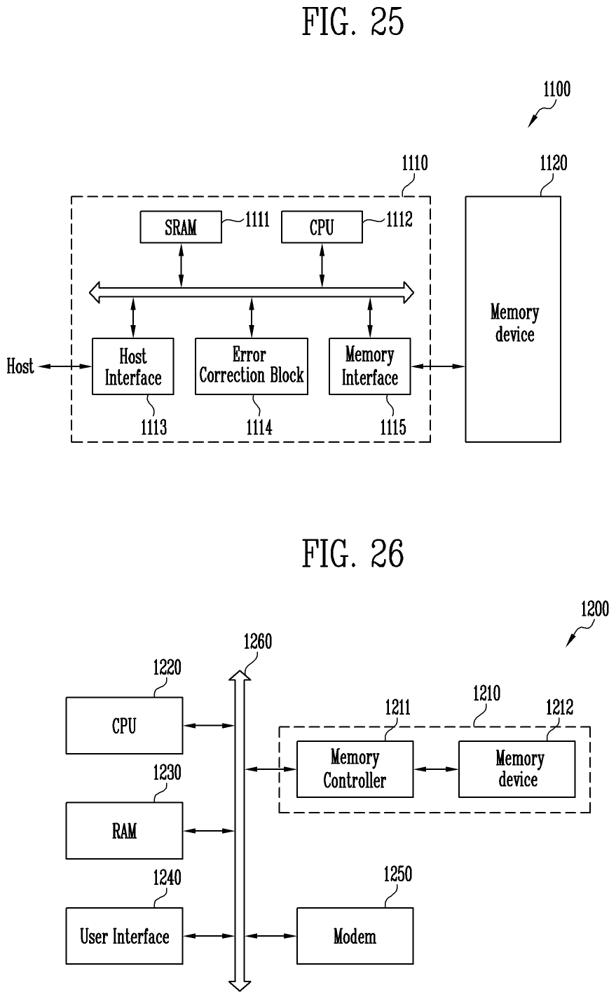

FIG. 25 is a block diagram illustrating a configuration of a memory system 1100 according to an embodiment of the present disclosure.

Referring to FIG. 25, the memory system 1100 includes a memory device 1120 and a memory controller 1110.

The memory device 1120 may be a multi-chip package including a plurality of flash memory chips. The memory device 1120 may include a peripheral circuit structure formed on a substrate and a stack formed on the peripheral circuit structure. The stack may include a cell stack. A gate contact structure connected to a gate conductive pattern of the cell stack may be connected to an interconnection structure included in the peripheral circuit structure by passing through the cell stack.

The memory controller 1110 may be configured to control the memory device 1120, and may include static random-access memory (SRAM) 1111, a central processing unit (CPU) 1112, a host interface 1113, an error correction block 1114, and a memory interface 1115. The SRAM 1111 is used as an operation memory of the CPU 1112, the CPU 1112 performs an overall control operation for data exchange of the memory controller 1110, and the host interface 1113 includes a data exchange protocol of a host connected to the memory system 1100. The error correction block 1114 detects and corrects an error included in data read from the memory device 1120. The memory interface 1115 performs interfacing with the memory device 1120. The memory controller 1110 may further include a read-only memory (ROM) or the like that stores code data for interfacing with the host.

The above-described memory system 1100 may be a memory card or a solid-state drive (SSD) in which the memory device 1120 and the memory controller 1110 are combined. For example, when the memory system 1100 is the SSD, the memory controller 1110 may communicate with the outside (for example, the host) through one of various interface protocols such as a universal serial bus (USB), a multimedia card (MMC), a peripheral component interconnection-express (PCI-E), a serial advanced technology attachment (SATA), a parallel advanced technology attachment (PATA), a small computer system interface (SCSI), an enhanced small disk interface (ESDI), and integrated drive electronics (IDE).

FIG. 26 is a block diagram illustrating a configuration of a computing system 1200 according to an embodiment of the present disclosure.

Referring to FIG. 26, the computing system 1200 may include a CPU 1220, random-access memory (RAM) 1230, a user interface 1240, a modem 1250, and a memory system 1210 electrically connected to a system bus 1260. When the computing system 1200 is a mobile device, a battery for supplying an operation voltage to the computing system 1200 may be further included, and an application chipset, an image processor, a mobile DRAM, and the like may be further included.

The memory system 1210 may include a memory device 1212 and a memory controller 1211. The memory device 1212 may be configured identically to the memory device 1120 described above with reference to FIG. 25. The memory controller 1211 may be configured identically to the memory controller 1110 described above with reference to FIG. 25.

What is claimed is:

1. A memory device comprising:
a gate stack formed on a cell region and a pass transistor region;
a plurality of cell plugs extending in a vertical direction in the gate stack of the cell region;
a plurality of gate contact structures extending in the vertical direction by passing through the gate stack of the pass transistor region; and
a plurality of pass transistors connected to the plurality of respective gate contact structures,
wherein each of the plurality of pass transistors has a cylindrical shape structure.

2. The memory device of claim 1, wherein each of the plurality of pass transistors comprises:
a channel pattern of a cylindrical shape structure connected to any one of the plurality of gate contact structures;
a gate insulating layer surrounding a sidewall of the channel pattern; and
a gate electrode surrounding a sidewall of the gate insulating layer.

3. The memory device of claim 2, wherein the plurality of pass transistors share the gate electrode.

4. The memory device of claim 2, wherein the gate electrode is a bulk silicon substrate, a silicon-germanium substrate, or an epitaxial thin film formed through a selective epitaxial growth method.

5. The memory device of claim 4, wherein the channel pattern is an epitaxial thin film.

6. The memory device of claim 5, wherein the channel pattern is a thin film obtained by growing the gate electrode in an epitaxial method.

7. The memory device of claim 2, further comprising:
a pass transistor contact structure connected to the gate electrode in the pass transistor region and extending in the vertical direction.

8. The memory device of claim 2, further comprising:
a source line formed over the gate stack of the cell region.

9. The memory device of claim 8, wherein the plurality of cell plugs extend inside the source line.

10. The memory device of claim 9, wherein each of the plurality of cell plugs includes a channel structure, and wherein the channel structure is directly connected to the source line.

11. The memory device of claim 10, further comprising:
an isolation structure disposed at a boundary between the cell region and the pass transistor region on the gate stack,
wherein the isolation structure physically and electrically separates the source line and the gate electrode.

12. A method of manufacturing a memory device, the method comprising:
forming a trench having a first depth at a boundary between a cell region and a pass transistor region and a plurality of first holes having a second depth in the pass transistor region by etching a first substrate including the cell region and the pass transistor region;
forming an isolation structure by filling an insulating layer in the trench and forming a gate insulating layer on a sidewall of the plurality of first holes;
forming channel patterns filling an inner portion of the plurality of first holes by growing the first substrate through an epitaxial growth method;
forming a stack in which first material layers and second material layers are alternately stacked on the entire structure including the cell region and the pass transistor region;
forming a plurality of cell plugs extending in a vertical direction in the stack of the cell region;
replacing the second material layers with conductive patterns for word line; and
forming a plurality of gate contact structures connected to the channel patterns through the stack of the pass transistor region.

13. The method of claim 12, wherein forming the plurality of gate contact structures comprises:
forming a plurality of second holes exposing the channel patterns by passing through the first material layers and the conductive patterns for word line, and forming a third hole exposing the first substrate; and
forming the plurality of gate contact structures and a pass transistor contact structure by filling the plurality of second holes and the third hole with a conductive material.

14. The method of claim 13, further comprising:
implanting ions into the channel patterns and the first substrate by performing an ion implantation process, and performing a rapid thermal annealing (RTA) process, after forming the plurality of second holes and the third hole.

15. The method of claim 12, wherein the first depth is equal to or deeper than the second depth.

16. The method of claim 12, further comprising:
forming a bit line connected to the plurality of cell plugs;
forming a conductive first connection structure on the bit line;
forming a complementary metal oxide semiconductor (CMOS) circuit on a second substrate;
forming a conductive second connection structure connected to the CMOS circuit on the second substrate; and
bonding a first bonding metal of the first connection structure and a second bonding metal of the second connection structure to each other so that the first connection structure and the second connection structure are connected to each other.

17. The method of claim 12, wherein forming the plurality of cell plugs comprises:
forming fourth holes extending into the first substrate by passing through the stack; and
filling the fourth holes with a memory layer and a channel layer.

18. The method of claim 17, further comprising:
etching the first substrate to expose the channel patterns and the isolation structure;
exposing the channel layer by removing the exposed memory layer after removing the first substrate on the cell region; and
forming a source line that is in contact with the channel layer on the cell region.

19. A memory device comprising:
a gate stack including a plurality of interlayer insulating layers and a plurality of conductive patterns that are alternately stacked from a first surface to a second surface;
a plurality of pass transistors arranged over the second surface of the gate stack; and
a plurality of gate contact structures configured to extend from the first surface of the gate stack and the second surface of the gate stack, and each of the gate contact structures configured to connect each of the pass transistors and each of the conductive patterns.

20. The memory device of claim 19, wherein each of the plurality of pass transistors comprises:
a channel pattern connected to a selected one of the plurality of gate contact structures;
a gate insulating layer surrounding a sidewall of the channel pattern; and
a gate electrode surrounding a sidewall of the gate insulating layer.

21. The memory device of claim 19,
wherein the gate stack comprises a memory cell array region and the word line contact region,
wherein the plurality of pass transistors is arranged at the word line contact region.
